(19) United States
(12) Patent Application Publication
(10) Pub. No.: US 2008/0017979 A1
(43) Pub. Date: Jan. 24, 2008

(54) SEMICONDUCTOR STRUCTURE HAVING EXTRA POWER/GROUND SOURCE CONNECTIONS AND LAYOUT METHOD THEREOF

(76) Inventors: Chia-Yuan Chang, Taichung County (TW); Tien-Yueh Liu, Hsinchu City (TW); Peng-Cheng Kao, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/777,288

(22) Filed: Jul. 13, 2007

Related U.S. Application Data
(60) Provisional application No. 60/807,719, filed on Jul. 19, 2006.

(51) Int. Cl. H01L 23/48; H01L 21/44

(52) U.S. Cl. 257/734; 438/652; 257/E23.151; 257/E21.476

(57) ABSTRACT

One exemplary embodiment of the present invention provides a semiconductor structure having a supply trunk and a supply rail, where a conduction path between the supply trunk and the supply rail includes at least two turning points. Another exemplary embodiment of the present invention provides a semiconductor structure having a first conductive layer, a second conductive layer, a third conductive layer, a first via coupled between the first conductive layer and the second conductive layer, and a second via coupled between the second conductive layer and the third conductive layer, where the first via is not aligned with the second via and the first via and the second via form a part of a supply net.

### CROSS REFERENCE TO RELATED APPLICATIONS

The application claims the benefit of U.S. Provisional Application No. 60/807,719, which was filed on Jul. 19, 2006 and is included herein by reference.

### BACKGROUND

The present invention is related to semiconductor structure, and more particularly to a power/ground source connection of a semiconductor structure and a layout method thereof.

Please refer to FIG. 1. FIG. 1 is a diagram illustrating a conventional follow pin connection 10 of a digital circuit. The conventional follow pin connection 10 is coupled between a digital logic block 11 and a supply trunk 12 to provide a supply source to the digital logic block 11. The conventional follow pin connection 10 of the digital circuit is implemented by a 0.18 um 1P6M semiconductor process. Therefore, there will be some signal routes existing in the layers (metals) between the supply trunk 12 and a supply rail 13 of the digital logic block 11. In other words, in this example, the supply trunk 12 consists of a 6^{th} metal (M6) of the 0.18 um 1P6M semiconductor process, the supply rail 13 consists of a 1^{st} metal (M1) of the 0.18 um 1P6M semiconductor process, and the signal routes can consist of the 2^{nd} metal (M2), 3^{rd} metal (M3), 4^{th} metal (M4), and 5^{th} metal (M5) of the 0.18 um 1P6M semiconductor process as shown in FIG. 1. The conventional follow pin connection 10 comprises an M1 region 14, an M2 region 15, an M3 region 16, an M4 region 17, an M5 region 18, an M6 region 19, a 1^{st} via (via1) 20, a 2^{nd} via (via2) 21, a 3^{rd} via (via3) 22, a 4^{th} via (via4) 23, and a 5^{th} via (via5) 24. Furthermore, the signal routes of the digital circuit comprise a plurality of signal routes 112a-112e as shown in FIG. 1.

In the conventional configuration shown in FIG. 1, the supply source from the supply trunk 12 only utilizes the follow pin connection 10 to supply power to or ground the digital logic block 11. When the digital logic block 11 needs a relatively high supply current from the supply source, the supply current flowing through the follow pin connection 10 may induce an electronic migration effect. Furthermore, because there is only one follow pin connection 10 coupled between the supply trunk 12 and the digital logic block 11, the IR-drop between the supply trunk 12 and the digital logic block 11 is large, resulting in a deviated supply voltage at the supply rail 13 of the digital logic block 11. This could cause the digital logic block 11 to malfunction.

### SUMMARY OF THE INVENTION

Therefore, the present invention discloses a semiconductor structure with an extra connection path between the power/ground source and a target logic block (e.g. a digital logic block).

According to an embodiment of the present invention, a semiconductor structure is disclosed. The semiconductor structure includes a supply trunk; and a supply rail, where a conduction path between the supply trunk and the supply rail comprises at least two turning points.

According to another embodiment of the present invention, a semiconductor structure is disclosed. The semiconductor structure includes a first conductive layer; a second conductive layer; a third conductive layer; a first via coupled between the first conductive layer and the second conductive layer; and a second via coupled between the second conductive layer and the third conductive layer, where the first via is not aligned with the second via and the first via and the second via form a part of a supply net.

According to another embodiment of the present invention, a layout method of a semiconductor structure is disclosed. The method includes: providing a preliminary circuit layout, the preliminary circuit layout comprising a plurality of conductive layers; and adding at least a via between two of the conductive layers, where the via forms part of a conduction path of a supply voltage.

According to another embodiment of the present invention, a layout method of a semiconductor structure is provided. The method includes: providing a preliminary circuit layout, the preliminary circuit layout comprising a plurality of conductive layers, wherein a supply trunk is defined on one conductive layer of the plurality of conductive layers, and a supply rail is defined on another conductive layer of the plurality of conductive layers; and adding at least a follow pin between the supply trunk and the supply rail.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a conventional follow pin connection of a digital circuit.

FIG. 2 is a diagram illustrating a semiconductor structure according to an embodiment of the present invention.

FIG. 3 is a diagram illustrating a layout method of the semiconductor structure in FIG. 2 according to an embodiment of the present invention.

FIG. 4 is a top view of each conductive layer defined by the preliminary circuit layout.

FIG. 5 is a top view of each conductive layer of the semiconductor structure illustrating the layout with the newly defined conductive regions.

FIG. 6 is a top view of each conductive layer of the semiconductor structure illustrating the layout with the newly added vias.

FIG. 7 shows portions of the semiconductor structure of FIG. 6.

FIG. 8 is a simplified diagram showing variations of conduction paths in different semiconductor structures.

FIG. 9 is another simplified diagram showing variations of conduction paths in different semiconductor structures.

### DETAILED DESCRIPTION

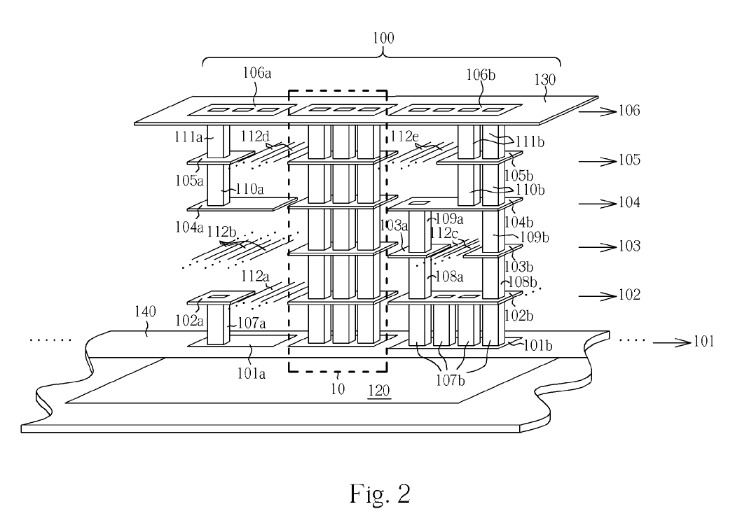

Please refer to FIG. 2. FIG. 2 is a diagram illustrating a semiconductor structure 100 according to an embodiment of the present invention. In this embodiment, a power connection between a supply trunk 130 and at least one digital logic block 120 are shown, and the semiconductor structure 100 is fabricated by a 0.18 um 1P6M semiconductor process. As shown in FIG. 2, the power connection of the digital logic block 120 includes a conventional follow pin connection 10, and further description of the follow pin connection 10 is omitted here for brevity. The present invention is not limited to the field of 0.18 um 1P6M semiconductor processes. Furthermore, the detailed description of layer construction of the well-known 0.18 um 1P6M semiconductor process is also omitted. In addition to the conventional follow pin connection 10, the semiconductor structure 100 comprises a first conductive layer 101, a second conductive layer 102, a third conductive layer 103, a fourth conductive layer 104, a fifth conductive layer 105, a sixth conductive layer 106, a plurality of first vias 107a, 107b, a plurality of second vias 108a, 108b, a plurality of third vias 109a, 109b, a plurality of fourth vias 110a, 110b, a plurality of fifth vias 111a, 111b, and a plurality of signal routes 112a-112e. The first conductive layer 101 has first conductive regions 101a and 101b formed thereon; the second conductive layer 102 has second conductive regions 102a and 102b formed thereon; the third conductive layer 103 has third conductive regions 103a and 103b formed thereon; the fourth conductive layer 104 has fourth conductive regions 104a and 104b formed thereon; the fifth conductive layer 105 has fifth conductive regions 105a and 105b formed thereon; and the sixth conductive layer 106 has sixth conductive regions 106a and 106b formed thereon. The sixth conductive regions 106a and 106b serve as supply regions formed on a supply trunk 130, and the first conductive regions 101a and 101b serve as supply rails 140 of a digital logic block 120. Please note that the first, second, third, fourth, fifth, and sixth conductive layers 101-106 correspond to metal layers (M1-M6) respectively of the 0.18 um 1P6M semiconductor process, and the first, second, third, fourth, fifth, and sixth vias 107-111 correspond to vias (via1-via6) respectively of the 0.18 um 1P6M semiconductor process.

In the exemplary structure shown in FIG. 2, the first via 107a has one terminal directly connected to the first conductive region 101a and another terminal directly connected to the second conductive region 102a; the first via 107b has one terminal directly connected to the first conductive region 101b and another terminal directly connected to the second conductive region 102b; the second via 108a has one terminal directly connected to the second conductive region 102b and another terminal directly connected to the third conductive region 103a; the second via 108b has one terminal directly connected to the second conductive region 102b and another terminal directly connected to the third conductive region 103b; the third via 109a has one terminal directly connected to the third conductive region 103a and another terminal directly connected to the fourth conductive region 104b; the third via 109b has one terminal directly connected to the third conductive region 103b and another terminal directly connected to the fourth conductive region 104b; the fourth via 110a has one terminal directly connected to the fourth conductive region 104a and another terminal directly connected to the fifth conductive region 105a; the fourth via 110b has one terminal directly connected to the fourth conductive region 104b and another terminal directly connected to the fifth conductive region 105b; the fifth via 111a has one terminal directly connected to the fifth conductive region 105a and another terminal directly connected to the sixth conductive region 106a; and the fifth via 111b has one terminal directly connected to the fifth conductive region 105b and another terminal directly connected to the sixth conductive region 106b. All conductive regions and all vias that are used to conduct supply voltage (power voltage or ground voltage) form a supply net.

Furthermore, the signal route 112a passes through the second conductive layer 102 between the second conductive region 102a and the follow pin connection 10; the signal route 112b passes through the third conductive layer 103 directly below the fourth conductive region 104a; the signal route 112c passes through the third conductive layer 103 between the third conductive region 103a and the third conductive region 103b; the signal route 112d passes through the fifth conductive layer 105 between the fifth conductive region 105a and the follow pin connection 10; the signal route 112e passes through the fifth conductive layer 105 between the fifth conductive region 105b and the follow pin connection 10. Accordingly, the structure that comprises the first via 107b, the second conductive region 102b, the second vias 108a and 108b, the third conductive regions 103a and 103b, the third vias 109a and 109b, the fourth conductive region 104b, the fourth via 110b, the fifth conductive region 105b, and the fifth via 111b forms an extra power connection between the supply trunk 130 and the supply rail 140 of the digital logic block 120. Therefore, when the digital logic block 120 needs to consume a supply current from the supply trunk 130, except for the conventional follow pin connection 10, the supply current is able to have an extra path to reach the digital logic block 120. Accordingly, because an extra parallel current path is built, the extra power connection can lessen the IR-drop effects of the follow pin connection 10, consequently lessening the electronic migration effect of the follow pin connection 10.

Alternatively, the first floating path formed by the first via 107a and the second conductive region 102a, and the second floating path formed by the fourth conductive region 104a, the fourth via 110a, the fifth conductive region 105a, and the fifth via 111a can both be viewed as capacitive devices, which can block a portion of noise generated from the supply trunk 130 being delivered to the digital logic block 120. In addition, as can be seen, these extra connections and floating paths are fabricated using spare areas of the semiconductor structure 100. Therefore, adding these extra connections and floating routes between the supply trunk 130 and the digital logic block 120 does not increase the chip size.

Please note that the structure of the extra power connection, the first floating path, and the second floating path are not limited to the structure shown in FIG. 2. A layout designer can add extra power connections between a supply trunk and a digital logic block according to the distribution of the existing signal routes. In other words, according to the present invention, the spare areas between the supply trunk and the digital logic block may be utilized to establish a plurality of extra power connections and floating paths. Please note that the supply trunk 130 of the semiconductor structure 100 in this embodiment is a power trunk; however, it is clear that the supply trunk 130 can be replaced by a ground trunk of the semiconductor structure 100, and the supply rail 140 of the digital logic block 120 can be replaced by a ground rail of the digital logic block 120. These modifications still obey the spirit of the present invention.

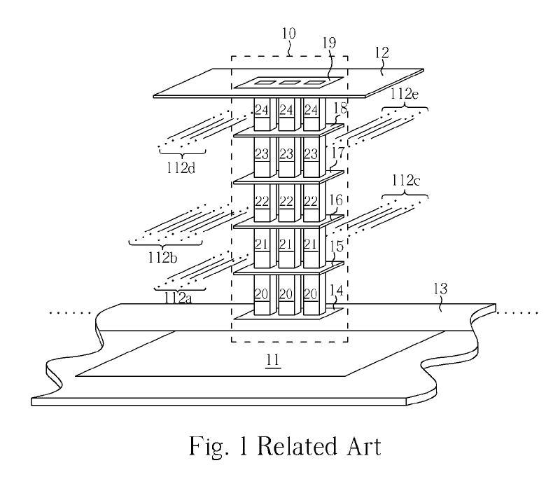

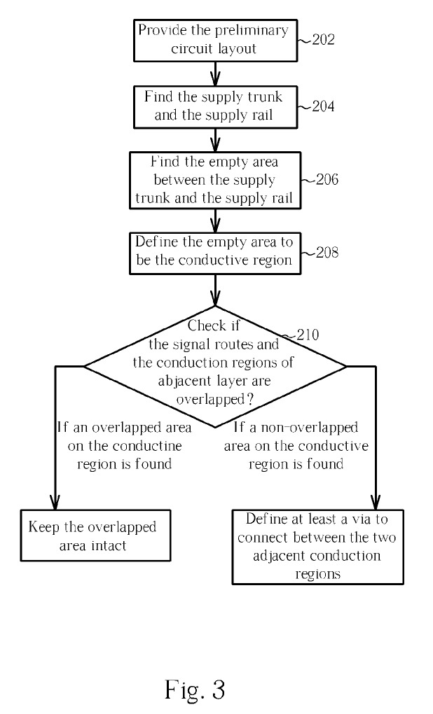

Please refer to FIG. 3. FIG. 3 is a diagram illustrating a layout method of the semiconductor structure 100 in FIG. 2 according to an embodiment of the present invention. As mentioned above, the aim of the present disclosure is to add extra power/ground connection(s) and/or floating path(s) to the conventional semiconductor structure, for example, the semiconductor structure shown in FIG. 1. In the following, a circuit layout as per the semiconductor structure shown in FIG. 1 is referred to as a preliminary circuit layout of the desired semiconductor structure 100 shown in FIG. 2. In other words, the preliminary circuit layout defines the digital logic block 120, the follow pin connection 10, the supply trunk 130, and the signal routes 112a-112e as shown in FIG. 2. Furthermore, because the layout method is for the well-known 0.18 um 1P6M semiconductor process, the detailed description related to the 0.18 um 1P6M semiconductor process is omitted here for brevity. It should be noted, however, that the present invention is not limited to the field of 0.18 um 1P6M semiconductor processes. Briefly, the layout method of the semiconductor structure 100 comprises the steps detailed below:
Step 202: Provide the preliminary circuit layout that is implemented by the 0.18 um 1P6M semiconductor process;
Step 204: Examine the preliminary circuit layout to find the supply trunk 130 and the supply rail 140 of the digital logic block 120;
Step 206: Find the spare area between the supply trunk 130 and the supply rail 140 of the digital logic block 120 in each conductive layer (i.e. the areas without the signal routes 112a-112e);
Step 208: Define the spare areas to be the conductive regions; and
Step 210: Check if each signal route 112a, . . . , 112e and conductive regions of an adjacent conductive layer are overlapped, wherein when a non-overlapped area on the conductive region is found, define at least a via to connect between two adjacent conductive regions, and when an overlapped area on the conductive regions is found, keep the overlapped area intact.

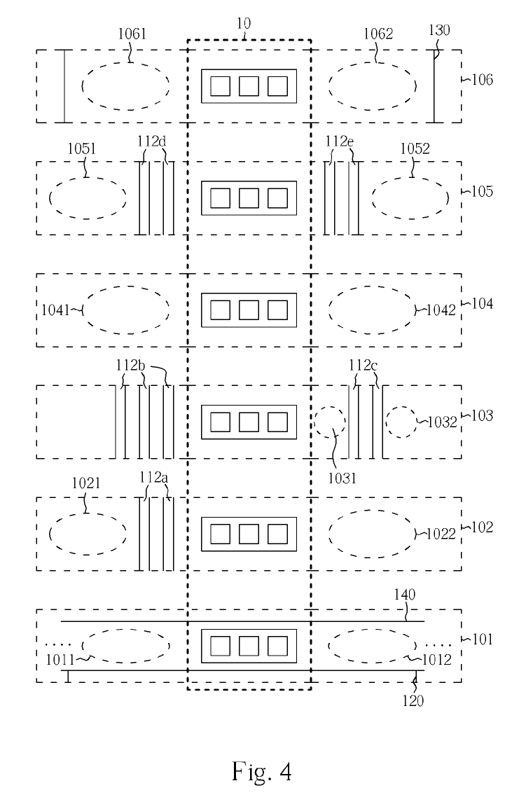

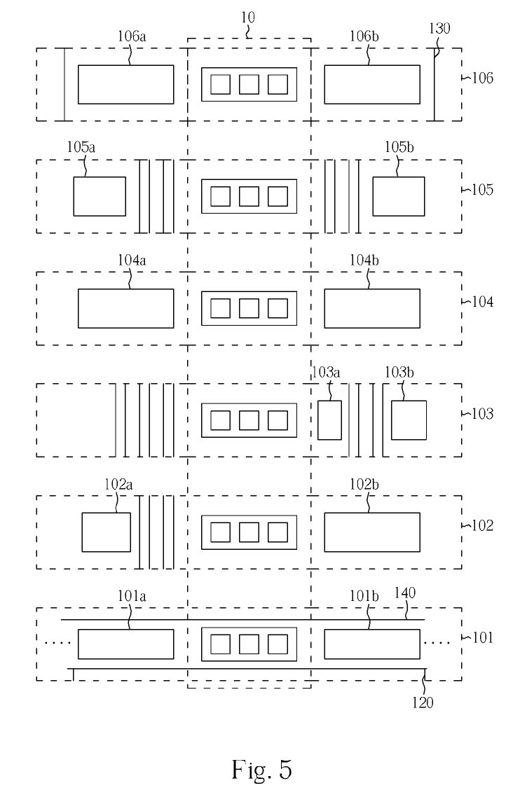

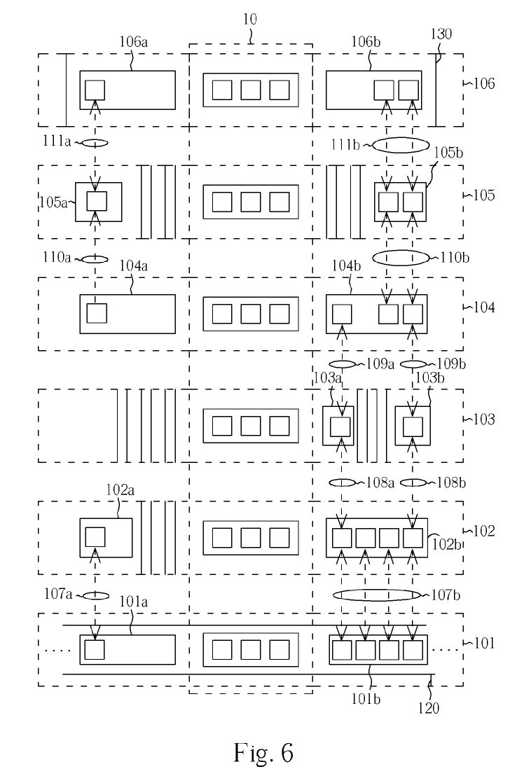

To further illustrate the disclosed layout method, please refer to FIG. 4, FIG. 5, and FIG. 6. FIG. 4 is a top view of each conductive layer 101-106 as defined by the preliminary circuit layout. FIG. 5 is a top view of each conductive layer 101-106 of the semiconductor structure 100 illustrating the layout with the newly defined conductive regions. FIG. 6 is a top view of each conductive layer 101-106 of the semiconductor structure 100 illustrating the layout with the newly added vias. It should be noted that the preliminary circuit layout could be created using any conventional software tools (step 202). Then, as can be seen, the supply trunk 130 and the supply rail 140 of the digital logic block 120 are positioned on the sixth conductive layer 106 and first conductive layer 101 respectively (step 204). Accordingly, spare areas 1011 and 1012 can be found on the first conductive layer 101, spare areas 1021 and 1022 can be found on the second conductive layer 102, spare areas 1031 and 1032 can be found on the third conductive layer 103, spare areas 1041 and 1042 can be found on the fourth conductive layer 104, spare areas 1051 and 1052 can be found on the fifth conductive layer 105, and spare areas 1061 and 1062 can be found on the sixth conductive layer 106 (step 206).

After the spare areas are identified from the given preliminary circuit layout, the flow proceeds to defining these found spare areas as conductive regions (shown in FIG. 5). According to the spare areas in FIG. 4, the first conductive regions 101a and 101b are formed on the first conductive layer 101, the second conductive regions 102a and 102b are formed on the second conductive layer 102, the third conductive regions 103a and 103b are formed on the third conductive layer 103, the fourth conductive regions 104a and 104b are formed on the fourth conductive layer 104, the fifth conductive regions 105a and 105b are formed on the fifth conductive layer 105, and the sixth conductive regions 106a and 106b are formed on the sixth conductive layer 106 (step 208).

Next, the flow proceeds to selectively adding vias between newly defined conductive regions according to specific rules. In this embodiment, adding an extra via is not allowed if this added via will impede normal operation of the digital logic block 120. For example, the layout method of the present invention avoids adding extra vias that will be coupled to signal routes defined by the preliminary circuit layout. Therefore, step 210 first checks if each of the signal routes 112a-112e and the conductive regions of an adjacent conductive layer are overlapped. Then, the flow defines at least a via to connect between two adjacent conductive regions when a non-overlapped area on the conductive region is found; while keeping an overlapped area intact. According to the conductive regions in FIG. 5, the newly added vias are shown in FIG. 6, where the first via 107a is added between the overlapped region of the first conductive region 101a and the second conductive region 102a, the first via 107b is added between the overlapped region of the first conductive region 101b and the second conductive region 102b; the second via 108a is added between the overlapped region of the second conductive region 102b and the third conductive region 103a, the second via 108b is added between the overlapped region of the second conductive region 102b and the third conductive region 103b; the third via 109a is added between the overlapped region of the third conductive region 103a and the fourth conductive region 104b, the third via 109b is added between the overlapped region of the third conductive region 103b and the fourth conductive region 104b; the fourth via 110a is added between the overlapped region of the fourth conductive region 104a and the fifth conductive region 105a, the fourth via 110b is added between the overlapped region of the fourth conductive region 104b and the fifth conductive region 105b; and the fifth via 111a is added between the overlapped region of the fifth conductive region 105a and the sixth conductive region 106a, the fifth via 111b is added between the overlapped region of the fifth conductive region 105b and the sixth conductive region 106b (step 210).

There are many possible procedures to add extra vias in a supply net. For example, one can first identify all possible conductive regions of all conductive layers to see if there is any possibility to form a conduction path between the supply trunk and the supply rail. If it is possible to form a conduction path, extra vias are then added. One can choose to add vias from bottom to top, that is, from the supply rail to the supply trunk. In this manner, vias between the first conductive layer and the second conductive layer are added, and then vias between the second conductive layer and the third conductive layer, and so on. In this embodiment, vias are added layer by layer sequentially from bottom to top.

In another embodiment, after all conductive regions are defined, vias are added between conductive regions of any two adjacent conductive layers regardless of whether a conduction path is possible to create.

In still another embodiment, one can choose any two adjacent conductive layers and determine whether to add extra vias in between. No specific order is needed in adding extra vias in this embodiment.

Based on the semiconductor structure defined by the preliminary circuit layout, the extra power connection, the first floating path, and the second floating path of the semiconductor structure 100 in FIG. 2 are added, accordingly.

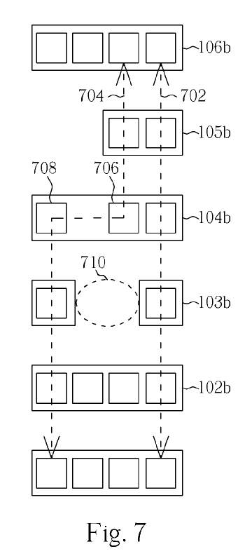

FIG. 7 shows portions of the semiconductor structure of FIG. 6. With reference to FIG. 7, a conduction path 702 is a path from the conductive region 106b to the conductive region 101b through conductive regions 105b, 104b, 103b, and 102b. The conduction path 702 is formed by vias coupled between conductive regions of adjacent conductive layers. The conduction path 702 is straight without any turning points. Vias forming the conduction path are not shown in the preliminary circuit layout and are added later as a follow pin. A follow pin is defined as a straight conduction path formed by vias from a supply trunk to a supply rail.

Another conduction path 704 is also path from the conductive region 106b to the conductive region 101b through conductive regions 105b, 104b, 103b, and 102b. The conduction path 704 is also formed by vias coupled between conductive regions of adjacent conductive layers. However, the conduction path 704 is not a straight one. The conduction path 704 has two turning points 706 and 708 to avoid passing though an area that has been occupied by a signal route (the area 710 for example). A conduction path defined by the preliminary circuit layout is always straight and has no turning points (follow pin connection 10 for example).

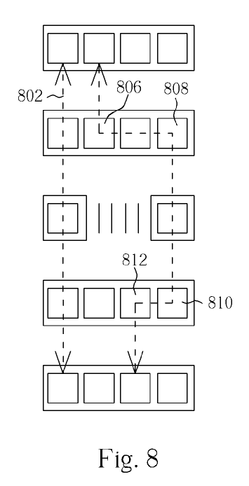

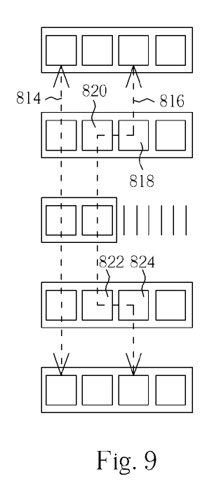

FIG. 8 and FIG. 9 are simplified diagrams showing variations of conduction paths in different semiconductor structures. With reference to FIG. 8, the conduction path 802 goes from a top conductive layer (a supply trunk is defined thereon) all the way down to a bottom conductive layer (a supply rail is defined thereon). The conduction path 802 is thus a follow pin. The conduction path 804 is also from top to bottom conductive layer, but with four turning points 806, 808, 810, and 812. The presence of the turning points is to avoid passing though an area that has been occupied by a signal route.

With reference to FIG. 9, the conduction path 814 goes from a top conductive layer all the way down to a bottom conductive layer. The conduction path 804 is thus a follow pin. The conduction path 816 is also from top to bottom conductive layer, but with four turning points 818, 820, 822, and 824. The presence of the turning points is to avoid passing though an area that has been occupied by a signal route.

Other conduction paths are possible by selecting different vias between conductive layers. All conduction paths presented in FIG. 8 and FIG. 9 are formed by vias that are added after the completion of the preliminary circuit layout. Conduction paths can also be defined from a supply rail to a supply trunk. Conduction paths can be bidirectional. Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a supply trunk; and
a supply rail, wherein a conduction path between the supply trunk and the supply rail comprises at least two turning points.

2. The semiconductor structure of claim 1, wherein the supply trunk is coupled to a power voltage.

3. The semiconductor structure of claim 1, wherein the supply trunk is coupled to a ground voltage.

4. A semiconductor structure, comprising:
a first conductive layer;
a second conductive layer;
a third conductive layer;
a first via coupled between the first conductive layer and the second conductive layer; and
a second via coupled between the second conductive layer and the third conductive layer, wherein the first via is not aligned with the second via and the first via and the second via form a part of a supply net.

5. The semiconductor structure of claim 4, wherein no via between the second conductive layer and the third conductive layer is aligned with the first via.

6. The semiconductor structure of claim 4, wherein no via between the first conductive layer and the second conductive layer is aligned with the second via.

7. The semiconductor structure of claim 4, further comprising a supply trunk, the supply trunk being electrically coupled to the third conductive layer.

8. The semiconductor structure of claim 7, wherein the supply trunk is coupled to a power voltage.

9. The semiconductor structure of claim 7, wherein the supply trunk is coupled to a ground voltage.

10. The semiconductor structure of claim 4, further comprising a supply rail, the supply rail being electrically coupled to the first conductive layer.

11. The semiconductor structure of claim 4, wherein the first via and the second via are electrically coupled.

12. A layout method of a semiconductor structure, the method comprising:
providing a preliminary circuit layout, the preliminary circuit layout comprising a plurality of conductive layers; and
adding at least a via between two of the conductive layers, wherein the via forms part of a conduction path of a supply voltage.

13. The layout method of claim 12, wherein the supply voltage is a power voltage.

14. The layout method of claim 12, wherein the supply voltage is a ground voltage.

15. The layout method of claim 12, the step of adding at least a via further comprising:
identifying areas of each conductive layer that are not occupied by a signal route; and
adding vias between the unoccupied areas.

16. The layout method of claim 12, wherein a supply trunk is defined on one conductive layer of the plurality of conductive layers, a supply rail is defined on another conductive layer of the plurality of conductive layers, and the supply trunk and the supply rail are electrically coupled through the conduction path.

17. A layout method of a semiconductor structure, the method comprising:
providing a preliminary circuit layout, the preliminary circuit layout comprising a plurality of conductive layers, wherein a supply trunk is defined on one conductive layer of the plurality of conductive layers, and a supply rail is defined on another conductive layer of the plurality of conductive layers; and
adding at least a follow pin between the supply trunk and the supply rail.

18. The layout method of claim 17, wherein the supply trunk is coupled to a power voltage.

19. The layout method of claim 17, wherein the supply trunk is coupled to a ground voltage.

20. The layout method of claim 17, the step of adding at least a follow pin further comprising:
identifying areas of each conductive layer that are not occupied by a signal route; and
adding the follow pin through the unoccupied areas.
